(19) United States
(12) Patent Application Publication
(10) Pub. No.: US 2026/0229167 A1
(43) Pub. Date: Aug. 6, 2026

(54) DISPLAY PANEL AND DISPLAY DEVICE

(71) Applicant: TIANMA ADVANCED DISPLAY TECHNOLOGY INSTITUTE (XIAMEN) CO., LTD., Xiamen (CN)

(72) Inventors: Mengmeng XIE, Xiamen (CN); Wenxin JIANG, Xiamen (CN); Tianyi WU, Xiamen (CN)

(21) Appl. No.: 19/248,827

(22) Filed: Jun. 25, 2025

(30) Foreign Application Priority Data
Mar. 31, 2025 (CN) 202510390575.7

(51) Int. Cl. G09G 3/32; H10H 29/32; H10H 29/49

(52) U.S. Cl. CPC G09G 3/32; H10H 29/32; H10H 29/49; G09G 2300/0426; G09G 2300/0465; G09G 2310/0267; G09G 2310/0286; G09G 2320/0233

(57) ABSTRACT

Provided are a display panel and a display device. A display region of the display panel includes at least one first region and at least two second regions, and two second regions are located on two sides of a respective first region along a first direction, the at least one first region includes shift register units and first electrodes, and the at least two second regions include pixel circuits and first electrodes, and one first electrode is electrically connected to a respective one pixel circuit. The pixel circuits connected to n first electrodes in the respective first region are located in one of the two second regions, and the pixel circuits connected to m first electrodes in the respective first region are located in the other one of the two second regions, where n and m are both positive integers.

### CROSS-REFERENCE TO RELATED APPLICATIONS

The present application claims priority to Chinese Patent Application No. 202510390575.7, filed on Mar. 31, 2025, the content of which is incorporated herein by reference in its entirety.

### TECHNICAL FIELD

The present disclosure relates to the field of display technologies, and in particular, to a display panel and a display device.

### BACKGROUND

In the current design of frameless products, a shift register unit is provided below a light-emitting device, and the shift register unit is inwardly retracted relative to an edge of a display panel, occupying a position where a pixel circuit is originally provided, thereby causing the pixel circuit to be squeezed to an inner side of a display region. The squeezed pixel circuit is electrically connected to the light-emitting device via a connection line. With an increase in pixel density (Pixels Per Inch, PPI) or the influence of factors such as the demand for large-size products, the number of squeezed pixel circuits increases, resulting in an increase in the number of connection lines between two adjacent pixel rows. The connection lines occupy more space, thereby limiting the improvement of PPI and the transparent display effect.

### SUMMARY

Embodiments of the present disclosure provide a display panel and a display device, to solve the technical problem that an increased number of connection lines occupies more space and affects the improvement of PPI and the transparent display effect.

In a first aspect, embodiments of the present disclosure provides a display panel, where a display region of the display panel includes shift register units, first electrodes and pixel circuits, and one of the first electrodes is electrically connected to a respective one of the pixel circuits. The display region includes at least one first region and at least two second regions, two second regions of the at least two second regions are located on two sides of a respective first region along a first direction, the at least one first region includes the shift register units and the first electrodes, and the at least two second regions includes the pixel circuits and the first electrodes. The pixel circuits connected to n first electrodes of the first electrodes in the respective first region are located in one of the two second regions, and the pixel circuits connected to m first electrodes of the first electrodes in the respective first region are located in the other one of the two second regions, where n and m are both positive integers.

In a second aspect, embodiments of the present disclosure provide a display device, including the display panel according to any embodiment of the present disclosure.

### BRIEF DESCRIPTION OF DRAWINGS

In order to better illustrate the technical solutions in embodiments of the present disclosure or the related art, the drawings used in the description of the embodiments will be briefly illustrated as follows. It should be noted that, the drawings described below are merely some of, rather than all of the embodiments of the present disclosure. Based on these drawings, those skilled in the art can obtain other drawings without any creative efforts.

FIG. 1 is a schematic diagram of a display panel according to an embodiment of the present disclosure;

FIG. 2 is a partial schematic diagram at a region Q1 shown in FIG. 1;

FIG. 3 is another partial schematic diagram of a display panel according to an embodiment of the present disclosure;

FIG. 4 is a circuit schematic diagram of a shift register unit shown in FIG. 3;

FIG. 5 is another partial schematic diagram of a display panel according to an embodiment of the present disclosure;

FIG. 6 is a circuit schematic diagram of a shift register unit shown in FIG. 5;

FIG. 7 is another schematic diagram of a display panel according to an embodiment of the present disclosure;

FIG. 8 is another structural schematic diagram of a film layer of a display panel according to an embodiment of the present disclosure;

FIG. 9 is another schematic diagram of a display panel according to an embodiment of the present disclosure;

FIG. 10 is another schematic diagram of a display panel according to an embodiment of the present disclosure;

FIG. 11 is another schematic diagram of a display panel according to an embodiment of the present disclosure;

FIG. 12 is another schematic diagram of a display panel according to an embodiment of the present disclosure;

FIG. 13 is another schematic diagram of a display panel according to an embodiment of the present disclosure;

FIG. 14 is another schematic diagram of a display panel according to an embodiment of the present disclosure;

FIG. 15 is a schematic diagram of a pixel circuit according to an embodiment of the present disclosure;

FIG. 16 is a schematic diagram of a pixel circuit in a second region according to an embodiment of the present disclosure;

FIG. 17 is a schematic diagram of a pixel circuit in a third region according to an embodiment of the present disclosure;

FIG. 18 is another schematic diagram of a display panel according to an embodiment of the present disclosure;

FIG. 19 is another partial schematic diagram of a display panel according to an embodiment of the present disclosure;

FIG. 20 is another partial schematic diagram of a display panel according to an embodiment of the present disclosure;

FIG. 21 is another partial schematic diagram of a display panel according to an embodiment of the present disclosure;

FIG. 22 is another partial schematic diagram of a display panel according to an embodiment of the present disclosure;

FIG. 23 is another partial schematic diagram of a display panel according to an embodiment of the present disclosure;

FIG. 24 is another partial schematic diagram of a display panel according to an embodiment of the present disclosure; and

FIG. 25 is a schematic diagram of a display device according to an embodiment of the present disclosure.

### DESCRIPTION OF EMBODIMENTS

In order to more clearly illustrate objectives, technical solutions, and advantages of embodiments of the present disclosure, the technical solutions in embodiments of the present disclosure are clearly and completely described in details with reference to the drawings. It should be noted that, the embodiments described are only some rather than all of the embodiments of the present disclosure. Based on the embodiments of the present disclosure, all other embodiments obtained by those ordinary skilled in the art without creative efforts shall fall within the protection scope of the present disclosure.

Terms used in the embodiments of the present disclosure are only for the purpose of describing specific embodiments, but not intended to limit the present disclosure. Unless otherwise noted in the context, the singular form expressions “a/an”, “the”, and “said” used in the embodiments and appended claims of the present disclosure are also intended to represent plural form expressions thereof.

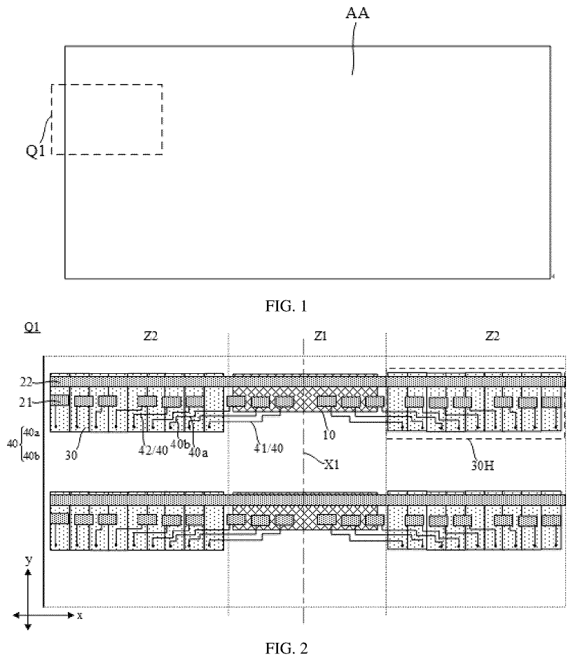

FIG. 1 is a schematic diagram of a display panel according to an embodiment of the present disclosure, and FIG. 2 is a partial schematic diagram at a region Q1 shown in FIG. 1. As shown in FIG. 2, a display region AA of the display panel includes shift register units 10, first electrodes 21 and pixel circuits 30, and each of the first electrodes 21 is electrically connected to one of the pixel circuits 30. The display region AA includes at least one first region Z1 and at least two second regions Z2, and two second regions Z2 are located on two sides of a respective first region Z1 along a first direction x. Each first region Z1 includes shift register units 10 and first electrodes 21, and each second region Z2 includes pixel circuits 30 and first electrodes 21. The pixel circuits 30 connected to n first electrodes 21 in a first region Z1 are located in one of two corresponding second regions Z2, and the pixel circuits 30 connected to m first electrodes 21 in the first region Z1 are located in the other one of the two corresponding second regions Z2, where n and m are both positive integers, and n+m is equal to a total number of the first electrodes 21 in the first region Z1.

Second electrodes 22 are further provided in the display region AA. Alternatively, the first electrode 21 is an anode, and the second electrode 22 is a cathode. The first electrode 21 and the second electrode 22 form an electrode pair, and are correspondingly connected to two terminals of a light-emitting device (not shown in FIG. 2). The light-emitting device may be a light-emitting diode (LED), such as a micro-LED or a mini-LED. That is, a first electrode 21 is connected between the light-emitting device and the corresponding pixel circuit 30. FIG. 2 shows that the first electrode 21 is electrically connected to the pixel circuit 30 via a connection line 40. FIG. 2 shows that a plurality of second electrodes 22 arranged in the first direction x are connected to each other to form a long strip common electrode. In some other implementations, the second electrodes 22 may also be arranged to be independent of each other, that is, the first electrode 21 and the second electrode 22 are both of a block structure, which are not shown in the drawings.

The display panel provided by the embodiments of the present disclosure is provided with a display region AA including at least one first region Z1 and at least two second region Z2. A first region Z1 is located between two second regions Z2, the shift register units 10 are arranged in the first region Z1, and the pixel circuits 30 connected to the first electrodes 21 located in the first region Z1 are respectively located in the two second regions Z2. Therefore, a plurality of first electrodes 21 in the first region Z1 are respectively connected to the corresponding pixel circuits 30 in the two second regions Z2 on left and right sides by connection lines, thereby reducing the number of connection lines 40 arranged on one side, and thus reducing an area occupied by the connection lines 40 on one side.

With the increase of the PPI, after the shift register units 10 are arranged in the display region AA, the number of the pixel circuits 30 compressed toward the interior of the display region AA will increase, resulting in an increase in the number of the misalignments between the first electrodes 21 and the pixel circuits 30, resulting in an increase in the number of the connection lines 40. As the size of the display panel increases, the load of the shift register units 10 can increase, and the driving capability of the shift register units 10 needs to be improved by increasing the size of the shift register units 10, so that the shift register units 10 located in the display region AA occupies more space, increasing the number of the connection lines 40. In the transparent display application, the increase in the number of the connection lines 40 can occupy the area of the transmission region, affecting the transparent display effect. The design of the embodiments of the present disclosure can reduce the occupation of the transmission region by the connection lines 40 arranged on one side, ensuring the transmittance of the transmission region, and improving the display effect of transparent display. In the non-transparent display, the design of the embodiments of the present disclosure can reduce a spacing distance between adjacent pixel circuits 30 in the second direction y, meeting high PPI display requirements.

In some implementations, as shown in FIG. 2, in the second region Z2, a plurality of pixel circuits 30 are arranged in circuit rows 30H in the first direction x, and in the first direction x, the shift register units 10 overlap with the circuit rows 30H correspondingly. It is equivalent to that the shift register units 10 separate the circuit rows 30H on the left and right sides thereof in the first direction x. From the overall display region, the shift register units 10 are arranged between the pixel circuits 30 arranged along the first direction x. This can be applied to the transparent display technologies, so that a transmission region is also left between adjacent shift register units 10 in the second direction y, thereby improving the uniformity of the overall transmittance of the display panel.

In some implementations, as shown in FIG. 2, the first region Z1 has a virtual line X1 extending along the second direction y, and the second direction y intersects with the first direction x. The n first electrodes 21 and the m first electrodes 21 are respectively located on two sides of the virtual line X1. That is, the first electrodes 21 on the left and right sides of the virtual line X1 are respectively connected by connection lines to the pixel circuits 30 located in the left-side and right-side second regions Z2. This arrangement can avoid the connection lines 40 connected to the two second regions Z2 from crossing, simplifying the wiring manner of the connection lines 40.

In an embodiment of the present disclosure, n and m are integers, n≥1, and m≥1. In some implementations, a difference between n and m is not large, so that a difference between the number of the connection lines 40 on the left side of the virtual line X1 and the number of the connection lines 40 on the right side of the virtual line X1 are not large, and widths occupied by the connection lines 40 arranged in the two second regions Z2 in the second direction y are substantially the same. In some implementations, n=m. In practice application, the number of the connection lines 40 on the left and right sides of the virtual line X1 can be designed according to the PPI of the display panel, the structure of the pixel circuit 30, and the structure of the shift register unit 10.

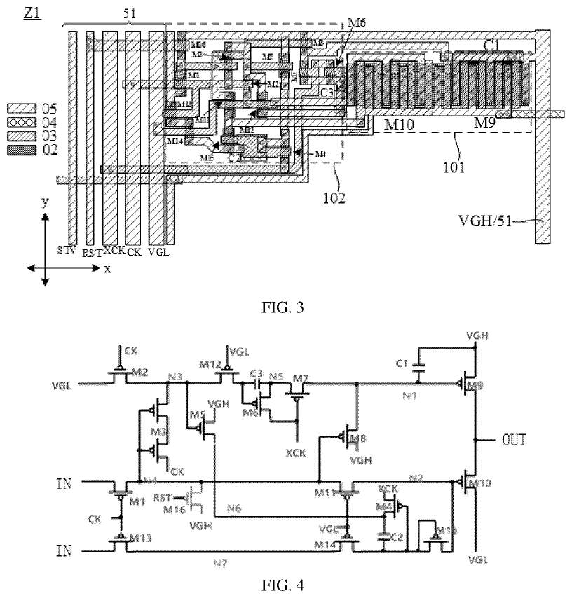

In some implementations, FIG. 3 is another partial schematic diagram of a display panel according to an embodiment of the present disclosure. FIG. 3 only shows the position of one shift register unit 10. FIG. 4 is a circuit schematic diagram of the shift register unit shown in FIG. 3. As shown in FIG. 3 and FIG. 4, the shift register unit 10 includes an output module 101 and a driving module 102. The shift register unit 10 includes sixteen transistors and three capacitors. The sixteen transistors include transistors from a first transistor M1 to a sixteenth transistor M16, and the three capacitors include a first capacitor C1, a second capacitor C2 and a third capacitor C3. The ninth transistor M9 and the tenth transistor M10 constitute the output module 101, and the other transistors constitute the driving module 102. FIG. 4 also shows nodes from N1 to N7, an input terminal IN and an output terminal OUT in the shift register unit. The display panel is provided with driving signal lines 51 including a first voltage signal line VGL, a second voltage signal line VGH, a first clock signal line CK, a second clock signal line XCK, a reset signal line RST, and a start signal line STV. The first voltage signal line VGL and the second voltage signal line VGH both transmit constant voltage signals, and a voltage value of a signal transmitted by the first voltage signal line VGL is less than a voltage value of a signal transmitted by the second voltage signal line VGH. That is, the first voltage signal line VGL transmits a low-level voltage signal, and the second voltage signal line VGH transmits a high-level voltage signal. An input terminal IN of a first stage of shift register unit 10 is connected to the start signal line STV, an input terminal IN of an i-th stage of shift register unit 10 is connected to an output terminal OUT of an i-th stage of shift register unit 10, where i is an integer, and i≥2.

It can be seen from FIG. 3 that the output module 101 and the driving module 102 are arranged in the first direction x in the first region Z1, so that a length of the shift register unit 10 in the first direction x is greater than a length of the shift register unit 10 in a second direction y, where the second direction y intersects with the first direction x. Typically, the second direction y is perpendicular to the first direction x. This arrangement can reduce a difference between the length of the shift register unit 10 in the second direction y and a length of the pixel circuit 30 in the second region Z2 in the second direction y. In the transparent display application, a length of the transmission region in the first region Z1 in the second direction y is close to a length of the transmission region in the second region Z2 in the second direction y, thereby improving the transparent display uniformity.

In addition, as shown in FIG. 3, the second voltage signal line VGH in the driving signal lines 51 is located on a side of the output module 101 away from the driving module 102, and the remaining signal lines are located on a side of the driving module 102 away from the output module 101. Such arrangement facilitates the electrical connection between the second voltage signal line VGH and the transistor in the output module 101, reduces winding, and ensures the signal output capability of the output module 101.

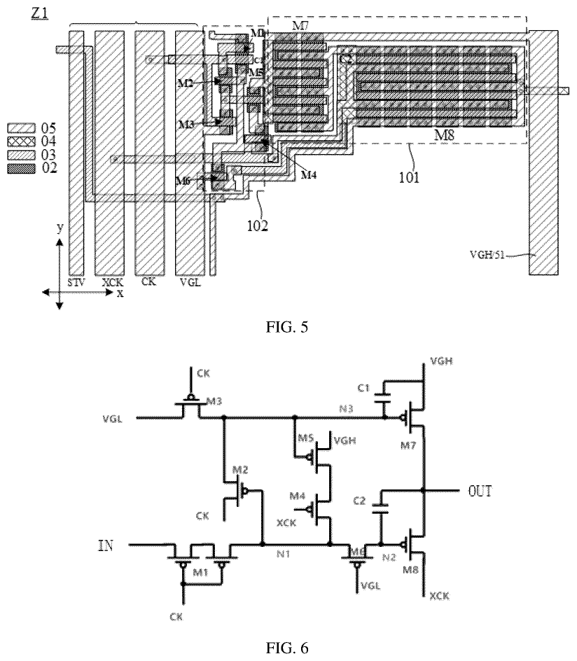

FIG. 3 shows a structure of a shift register unit. An embodiment of the present disclosure further provides another shift register unit. FIG. 5 is another partial schematic diagram of a display panel according to an embodiment of the present disclosure. FIG. 5 only shows the position of one shift register unit 10. FIG. 6 is a circuit schematic diagram of the shift register unit shown in FIG. 5. As shown in FIG. 5 and FIG. 6, the shift register unit 10 includes eight transistors and two capacitors. The eight transistors include transistors from a first transistor M1 to an eighth transistor M8, and the two capacitors include a first capacitor C1 and a second capacitor C2. The driving module 102 includes transistors from a first transistor M1 to a sixth transistor M6, and the output module 101 includes a seventh transistor M7 and an eighth transistor M8. FIG. 6 also shows nodes from N1 to N3, an input terminal IN and an output terminal OUT in the shift register unit. The driving signal lines 51 in the display panel include a first voltage signal line VGL, a second voltage signal line VGH, a first clock signal line CK, a second clock signal line XCK, and a start signal line STV. An input terminal IN of a first stage of shift register unit 10 is connected to the start signal line STV, an input terminal IN of an i-th stage of shift register unit 10 is connected to an output terminal OUT of an i-th stage of shift register unit 10, where i is an integer, and i≥2.

In the embodiment of FIG. 5, the output module 101 and the driving module 102 are arranged in the first direction x in the first region Z1, so that a length of the shift register unit 10 in the first direction x is greater than a length of the shift register unit 10 in the second direction y. In addition, the second voltage signal line VGH in the driving signal lines 51 is located on a side of the output module 101 away from the driving module 102, and the remaining signal lines are located on a side of the driving module 102 away from the output module 101. Such arrangement facilitates the electrical connection between the second voltage signal line VGH and the transistor in the output module 101, reduces winding, and ensures the signal output capability of the output module 101.

As shown in FIG. 2, the display panel includes a plurality of connection lines 40 including first connection lines 41 and second connection lines 42. The first connection lines 41 extend from the first region Z1 to the second region Z2, and the second connection lines 42 are located in the second region Z2. The first connection lines 41 are connected between the first electrodes 21 in the first region Z1 and the pixel circuits 30 electrically connected thereto, and the second connection lines 42 are connected between at least some of the first electrodes 21 in the second region Z2 and the pixel circuits 30 electrically connected thereto. In the embodiments of the present disclosure, the shift register units 10 are arranged in the first region Z1 in the display region AA, and the shift register units 10 occupy a position where the pixel circuits 30 are arranged, so that some of the pixel circuits 30 are compressed into the left-side and right-side second regions Z2. At least some of the first electrodes 21 in the second region Z2 and the first electrodes 21 in the first region Z1 can be misaligned with their corresponding pixel circuits 30. The first connection lines 41 are provided to establish electrical connections between the first electrodes 21 in the first region Z1 and the pixel circuits 30, and the second connection lines 42 are provided to establish electrical connections between the first electrodes 21 in the second region Z1 and the pixel circuits 30.

As shown in FIG. 2, each of at least some of the connection lines 40 includes at least one first line sub-segment 40a and at least one second line sub-segment 40b, and the first line sub-segment 40a and the second line sub-segment 40b are connected to each other. The first line sub-segment 40a extends along a first direction x, and the second line sub-segment 40b extends along a second direction y, where the second direction y intersects with the first direction x. At least some of the connection lines 40 are arranged in a stepped trace. Such an arrangement can make the plurality of connection lines 40 more compact when arranged, thereby saving space occupied by the arrangement of the plurality of connection lines 40.

In some implementations, a constant voltage signal line extending along the second direction y is arranged in the second region Z2, and the second line sub-segment 40b may be arranged to overlap with the constant voltage signal line, thereby improving a signal crosstalk problem. For example, the constant voltage signal line may be a power signal line electrically connected to the pixel circuits 30, or may be a constant voltage signal line electrically connected to the shift register units 10, such as the first voltage signal line VGL or the second voltage signal line VGH shown in FIG. 3.

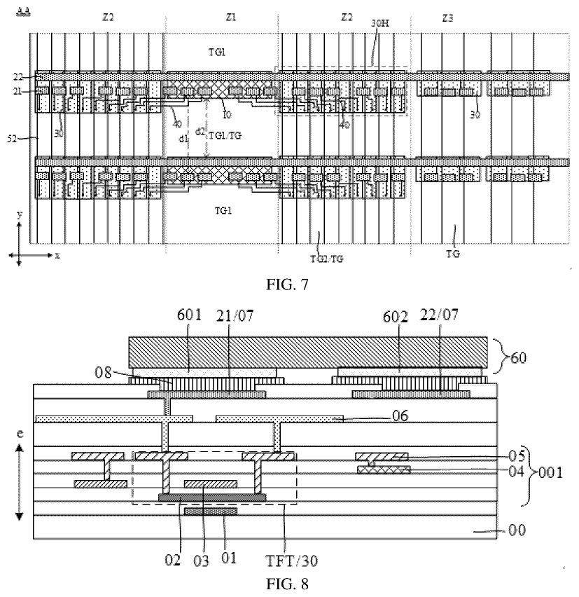

In some implementations, FIG. 7 is another schematic diagram of a display panel according to an embodiment of the present disclosure. As shown in FIG. 7, in the second region Z2, a plurality of pixel circuits 30 are arranged in circuit rows 30H in the first direction x. FIG. 7 is a top view, which can be understood that the direction perpendicular to the plane of the display panel is parallel to a top view direction. Along the direction perpendicular to the plane of the display panel, at least some of the connection lines 40 located in the second region Z2 overlaps with the circuit rows 30H. In the transparent display application, the display region AA is further provided with second signal lines 52 extending along the second direction y. In the second region Z2, the second signal lines 52 and the circuit rows 30H intersect to define a plurality of transmission regions TG. At least some of the connection lines 40 in the second region Z2 overlaps with the circuit rows 30H, so that the connection lines 40 do not affect the size of the transmission regions TG in the second region Z2 by densely arranging the connection lines 40 in the second region Z2, thereby ensuring the transmittance of the second region Z2 and improving the transparent display effect.

In addition, for the connection lines 40 routed in the first region Z1, the connection lines 40 are arranged to overlap with the shift register units 10 as much as possible, to reduce the influence on the transmittance of the first region Z1.

As shown in FIG. 7, the display region AA includes a first transmission region TG1 located in the first region Z1, and second transmission regions TG2 located in the second region Z2. In the first direction x, the first transmission region TG1 at least partially overlaps with the second transmission regions TG2, and the shift register units 10 at least partially overlap with the circuit rows 30H. In this way, the non-transmission region in the first region Z1 is substantially aligned with the non-transmission region in the second region Z2, and the transmission region in the first region Z1 is substantially aligned with the transmission region in the second region Z2, which can improve the uniformity of the overall transmittance in the display region AA.

In some implementations, each of the second transmission regions TG2 in the second region Z2 has substantially the same shape, so that the transmittance of the second region Z2 is more uniform.

In some other implementations, the shape of each second transmission region TG2 in the second region Z2 may be a rectangle, a nearly rectangle, or other shapes. In practice application, the shape of the second transmission region TG2 may be appropriately adjusted according to the wiring space requirement in the second region Z2.

In some implementations, FIG. 8 is another structural schematic diagram of a film layer of a display panel according to an embodiment of the present disclosure. As shown in FIG. 8, the display panel includes a substrate 00, and a light-shielding layer 01, a semiconductor layer 02, a first metal layer 03, a second metal layer 04, a third metal layer 05, a fourth metal layer 06 and a fifth metal layer 07 arranged above the substrate 00. FIG. 8 shows a position of a transistor TFT in the pixel circuit 30. An active layer of the transistor TFT is located in the semiconductor layer 02. In a direction e perpendicular to a plane of the substrate 00, the light-shielding layer 01 overlaps with the active layer of the transistor TFT. The light-shielding layer 01 is configured to shield the active layer of the transistor TFT from light at the substrate 00 side, thereby preventing light from irradiating the active layer to affect the performance of the transistor TFT. A gate of the transistor TFT is located in the first metal layer 03. One electrode plate of a storage capacitor in the pixel circuit 30 is provided in the second metal layer 04, and another electrode plate of the storage capacitor is located in the first metal layer 03. A source electrode and a drain electrode of at least part of the transistor TFT are provided on the third metal layer 05. The first metal layer 03 and the second metal layer 04 are made of a same material that includes molybdenum, and the third metal layer 05 includes titanium and/or aluminum, for example, a titanium/aluminum structure.

In addition, alternatively, a power supply structure is arranged in the fourth metal layer 06. The power supply structure may be, for example, a positive power supply structure connected to the pixel circuit 30. The positive power supply structure is configured to provide a first power signal Pvdd to the pixel circuit 30. A first electrode 21 and a second electrode 22 are arranged in the fifth metal layer 07, and are used for bonding and connecting a light-emitting device 60. For example, a positive electrode 601 of the light-emitting device 60 is connected to the first electrode 21 through an eutectic layer 08, a negative electrode 602 of the light-emitting device 60 is connected to the second electrode 22 through the eutectic layer 08, and the first electrode 21 is electrically connected to the pixel circuit 30. The fourth metal layer 06 and the fifth metal layer 07 may be made of the same material as the third metal layer 05, including titanium and/or aluminum.

In an embodiment of the present disclosure, the connection lines 40 and the first electrodes 21 are arranged in a same layer, and the connection lines 40 and the first electrodes 21 are manufactured in a same process without adding a new process.

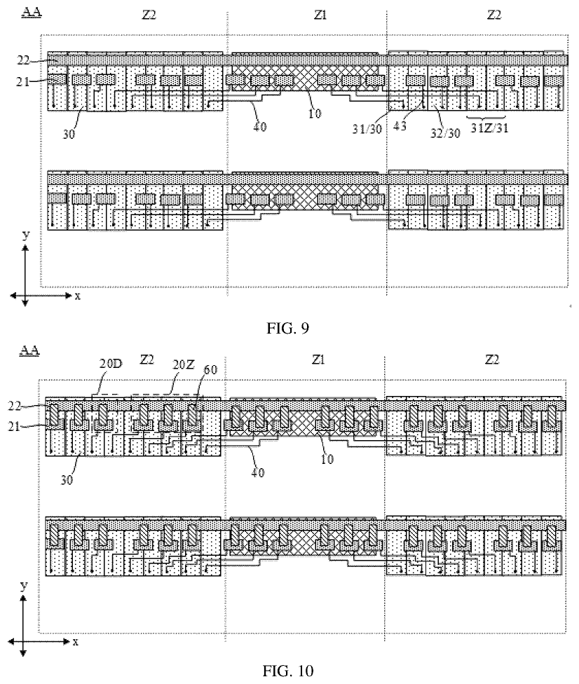

In some other implementations, FIG. 9 is another schematic diagram of a display panel according to an embodiment of the present disclosure. As shown in FIG. 9, the pixel circuits 30 in the second region Z2 includes first pixel circuits 31 and second pixel circuits 32; connection lines 40 are connected between the first pixel circuits 31 and the first electrodes 21 connected thereto, along a direction perpendicular to the plane of the display panel, the second pixel circuits 32 overlap with the first electrodes 21 connected thereto, and third line segments 43 are connected between the second pixel circuits 32 and the first electrodes 21. A plurality of first pixel circuits 31 continuously arranged in the first direction x form a pixel circuit group 31Z, and at least one second pixel circuit 32 is located between two adjacent pixel circuit groups 31Z. One pixel circuit group 31Z may include one, two or more first pixel circuits 31. In this implementation, the pixel circuits 30 connected to the first electrodes 21 in the first region Z1 are arranged in the second region Z2, and the connection lines 40 are provided to electrically connect the first electrodes 21 and the pixel circuits 30. The pixel circuits 30 in the second region Z2 are arranged densely, and the pixel circuits 30 overlapping with the first electrode 21 is also arranged in the second region Z2. When the first electrode 21 overlaps with the pixel circuit 30 in the second region Z2, the first electrode 21 is connected to the pixel circuit 30, so that the third line segment 43 between the first electrode 21 and the pixel circuit 30 is relatively short, and the voltage drop on the third line segment 43 is relatively small.

In addition, it can be seen from FIG. 9 that, due to the interleaved arrangement of the second pixel circuits 32 and the first pixel circuits 31 in the second region Z2, some of the connection lines 40 intersect with the third line segments 43. To prevent short circuits between the connection lines 40 and third line segments 43, the connection lines 40 and the third line segments 43 can be arranged on different layers, alternatively, the connection lines or the third line segments may adopt a bridge design at their intersection positions.

FIG. 9 shows that each of the pixel circuits 30 in the second region Z2 is connected to the connection line 40 at the same position, that is, the signal output terminals of the pixel circuits 30 are located at the same position. In some other implementations, the interleaved arrangement of the second pixel circuit 32 and the first pixel circuit 31 in the second region Z2 can differentiate positions of signal output terminals of the second pixel circuit 32 and the first pixel circuit 31. For example, by adjusting the arrangement of the transistors in the pixel circuit, the signal output terminal of the second pixel circuit 32 is located above the pixel circuit, while the signal output terminal of the first pixel circuit 31 is located below the pixel circuit, so that the third line segment 43 corresponding to the second pixel circuit 32 and the connection line 40 corresponding to the first pixel circuit 31 can be prevented from crossing, thereby avoiding the cross-line design, and saving the manufacturing process without adding a new wiring film layer.

In some other implementations, FIG. 10 is another schematic diagram of a display panel according to an embodiment of the present disclosure. As shown in FIG. 10, the display region AA further includes second electrodes 22 and light-emitting devices 60, a first electrode 21 and a second electrode 22 form an electrode pair 20D, and the second electrode 22 and the first electrode 21 are arranged in a same layer. Two terminals of a light-emitting device 60 are respectively electrically connected to the first electrode 21 and the second electrode 22 in one electrode pair 20D. The display region AA is divided into a plurality of electrode groups 20Z, and one electrode group 20Z includes N electrode pairs 20D, where N is a positive integer, and N≥2. FIG. 10 takes N=3 as an example.

Alternatively, colors of N light-emitting devices 60 correspondingly connected to one electrode group 20Z are different from one another. When N=3, three light-emitting devices 60 correspondingly connected to one electrode group 20Z include a red light-emitting device, a green light-emitting device and a blue light-emitting device.

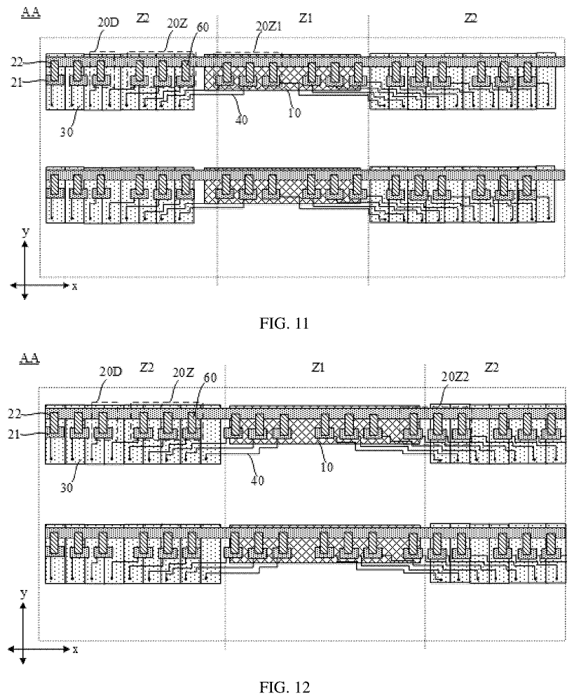

In some implementations, FIG. 11 is another schematic diagram of a display panel according to an embodiment of the present disclosure. As shown in FIG. 11, in each of at least one electrode group 20Z in the first region Z1, pixel circuits 30 connected to n1 first electrodes 21 are located in one second region Z2, and pixel circuits 30 connected to n2 first electrodes 21 are located in the other second region Z2, where n1 and n2 are both positive integers, and n1+n2=N. FIG. 11 takes N=3, n1=1, and n2=2 as an example. It can be seen that among three first electrodes 21 of an electrode group 20Z1, the pixel circuit 30 connected to one first electrode 21 is located in the second region Z2 on the right side, and the pixel circuits 30 connected to two first electrodes 21 are located in the second region Z2 on the left side. In practice application, depending on the size of the shift register unit 10, the structure of the pixel circuit 30 and the design of the PPI of the display panel, there may exist an electrode group 20Z1 as shown in FIG. 11. In application, it can be flexibly adjusted according to the panel structure, so that the wiring of the connection lines 40 in the two second regions Z2 on both sides of the first region Z1 is more balanced, and the occupied areas of the connection lines 40 in the two second regions Z2 are also relatively balanced. When applied in transparent display, transmittances of the two second regions Z2 can be made substantially consistent, thereby improving the transparent display effect.

In some implementations, FIG. 12 is another schematic diagram of a display panel according to an embodiment of the present disclosure. As shown in FIG. 12, in each of at least one electrode group 20Z, n3 first electrodes 21 are located in a first region Z1, and n4 first electrodes 21 are located in a second region Z2, where n3 and n4 are both positive integers, and n3+n4=N. FIG. 12 takes N=3, n3=1, and n4=2 as an example. It can be seen that among three first electrodes 21 of an electrode group 20Z2, one first electrode 21 is located in the first region Z1, and two first electrodes 21 are located in the second region Z2. In practice application, depending on the size of the shift register unit 10, the structure of the pixel circuit 30 and the design of the PPI of the display panel, there may exist an electrode group 20Z2 as shown in FIG. 12.

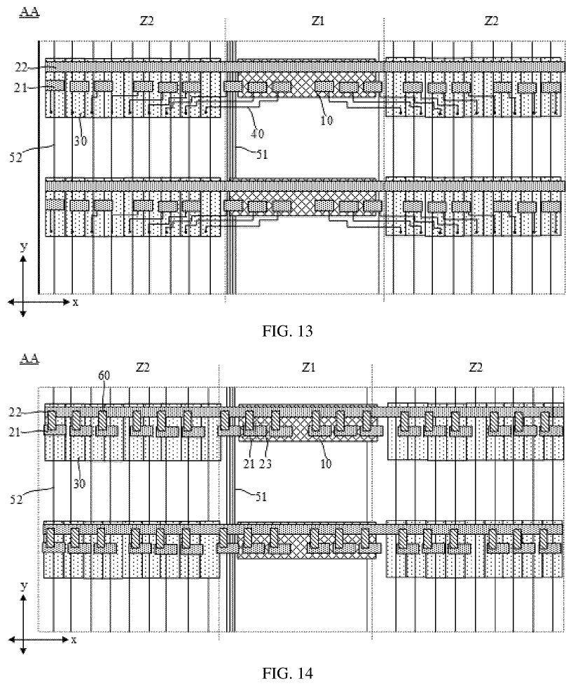

In some implementations, FIG. 13 is another schematic diagram of a display panel according to an embodiment of the present disclosure. As shown in FIG. 13, the display region includes driving signal lines 51 and second signal lines 52 extending along a second direction y, and the second direction y intersects with the first direction x. The shift register units 10 are electrically connected to the driving signal lines 51, and the pixel circuits 30 are electrically connected to the second signal lines 52. The second signal lines 52 include a data line. It can be understood in combination with FIG. 3 that a plurality of driving signal lines 51 need to be provided for a group of shift register units 10, and the number of the driving signal lines 51 in FIG. 13 is merely for illustration.

In the display panel, shift register units 10, first electrodes 21 and second electrodes 22 are provided in the first region Z1, and pixel circuits 30, first electrodes 21 and second electrodes 22 are provided in the second region Z2. The pixel circuits 30 that were originally required to be arranged in the first region Z1 are arranged in the second region Z2, so that the pixel circuits 30 in the second region Z2 are arranged relatively densely. In the display region AA, a first electrode 21 and a second electrode 22 are configured to be connected to a light-emitting device. For the overall display effect, arrangement rules of the first electrodes 21 in the first region Z1 and the second region Z2 are basically the same, while a first electrode 21 overlaps with a structure (such as a signal line, a pixel circuit 30 or a shift register unit 10) below the first electrode 21. There are many cases where the first electrode 21 overlaps with the underlying structure.

It can be seen from the top view of FIG. 13 that, along a direction perpendicular to the plane of the display panel, at least one first electrode 21 overlaps with both the driving signal line 51 and the shift register unit 10, and at least one first electrode 21 overlaps with both the second signal line 52 and the pixel circuit 30. In addition, in some implementations, at least one first electrode 21 overlaps with both the driving signal line 51 and the pixel circuit 30. In some implementations, at least one first electrode 21 overlaps with both the driving signal line 51 and the second signal line 52. Affected by the PPI of the display panel, the structure of the pixel circuit 30, the structure of the shift register unit 10, and the size of the first electrode 21, the first electrode 21 may overlap with a signal line or a circuit structure (such as the pixel circuit 30 and the shift register unit 10) below the first electrode 21, or the first electrode 21 may overlap with both a signal line and a circuit structure.

In some implementations, FIG. 14 is another schematic diagram of a display panel according to an embodiment of the present disclosure. FIG. 14 shows that the display region further includes a redundant electrode 23, and does not show a connection line between the first electrode 21 and the pixel circuit 30. As shown in FIG. 14, the display region AA includes driving signal lines 51 and second signal lines 52 extending along a second direction y, and the second direction y intersects with the first direction x. The shift register units 10 are electrically connected to the driving signal lines 51, and the pixel circuits 30 are electrically connected to the second signal lines 52. The second signal lines 52 includes a data line. The display region AA further includes a redundant electrode 23. The redundant electrode 23 and one first electrode 21 are connected to the same pixel circuit 30, and one first electrode 21 is correspondingly provided with at least one redundant electrode 23. FIG. 14 takes an example in which the redundant electrode 23 and the first electrode 21 are electrically connected as an integrated structure, that is, an electrode with a relatively large area, a part of which is the first electrode 21 and the other part of which is the redundant electrode 23. In other implementations, the redundant electrode 23 and the first electrode 21 are two independent electrodes. The redundant electrode 23 is designed to repair the defective pixel in the display panel. FIG. 14 shows that there is no light-emitting device 60 bonded to the positions of the redundant electrodes 23. In some other implementations, the redundant electrodes 23 at some positions are bound with light-emitting devices 60, but the light-emitting device devices 60 at these positions cannot emit light due to damage. During the manufacturing process, two electrodes A and B are arranged at positions corresponding to one sub-pixel, and the light-emitting device 60 is bound at a position corresponding to the electrode A during bonding. Then, a lighting test is performed. When a dead pixel (that is, a light-emitting device 60 that cannot emit light normally) is detected, one light-emitting device 60 is rebound to the electrode B at the dead pixel. In this case, the electrode B is the first electrode 21, while the light-emitting device bound at the electrode A may either be removed or retained. The electrode A is the redundant electrode 23.

It can be seen from the top view of FIG. 14 that, along a direction perpendicular to the plane of the display panel, at least one redundant electrode 23 overlaps with the driving signal lines 51, and/or at least one redundant electrode 23 overlaps with the second signal lines 52. FIG. 14 shows that there is no light-emitting device 60 bonded to the positions of the redundant electrodes 23.

FIG. 14 shows a scheme for defect repair using redundant electrodes 23. In some other implementations, when a pixel has a defect, it can be repaired in situ. That is, when the pixel has a defect, the defective light-emitting device is first removed, and then a new light-emitting device is re-bonded at the original position using the first electrode 21 and the second electrode 22.

In some implementations, as shown in FIG. 7, in the second direction y, a distance between two adjacent first electrodes 21 is d1, and a distance between two adjacent shift register units 10 is d2, where d1 is greater than d2. The corresponding positions of the first electrode 21 and the second electrode 22 are used to bond the light-emitting device. In the first region Z1, d1 is greater than d2, so that the first electrode 21 overlaps with the shift register unit 10. The first electrode 21 and the second electrode 22 are generally made of a metal material. The embodiment of the present disclosure can prevent the first electrode 21 from occupying the space of the transmission region when applied in the transparent display, and improving the transmittance of the transparent display. Further, the first electrode 21 and the second electrode 22 in the first region Z1 both overlap with the shift register unit 10, so that the light-emitting device can also overlap with the shift register unit 10, thereby further preventing the light-emitting device from occupying the space of the transmission region.

As shown in FIG. 7, the display region AA further includes a third region Z3 that includes pixel circuits 30, first electrodes 21 and second electrodes 22. An arrangement density of the pixel circuits 30 in the third region Z3 is smaller than an arrangement density of the pixel circuits 30 in the second region Z2. The third region Z3 is a regular region in the display region AA, and the second region Z2 is a densely-arranged region of the pixel circuits 30 in the display region AA. In the third region Z3, the first electrode 21 overlaps with the pixel circuit 30 connected thereto.

In some implementations, it can be seen from FIG. 7 that a length of the pixel circuit 30 in the second region Z2 in the first direction x is less than a length of the pixel circuit 30 in the third region Z3 in the first direction x, and/or a length of the pixel circuit 30 in the second region Z2 in the second direction y is greater than a length of the pixel circuit 30 in the third region Z3 in the second direction y, where the second direction y intersects with the first direction x. Such arrangement can compress the length occupied by a single pixel circuit 30 in the second region Z2 in the first direction x, so that a relatively large number of pixel circuits 30 can be arranged in the second region Z2. In the embodiment of the present disclosure, the pixel circuits 30 in the second region Z2 and the pixel circuits 30 in the third region Z3 are arranged differently, ensuring that the driving performance of each pixel circuit 30 is consistent, and further ensuring that a sufficient number of pixel circuits 30 are arranged in the second region Z2.

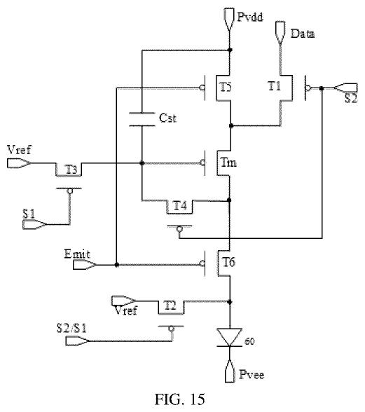

FIG. 15 is a schematic diagram of a pixel circuit according to an embodiment of the present disclosure. As shown in FIG. 15, the pixel circuit includes a driving transistor Tm, a data writing transistor T1, an electrode reset transistor T2, a gate reset transistor T3, a threshold compensation transistor T4, a first light-emitting control transistor T5, a second light-emitting control transistor T6, and a storage capacitor Cst. The pixel circuit needs to be driven by a scanning signal S1, a scanning signal S2, a light-emitting control signal Emit, a reset signal Vref, a first power signal Pvdd, and a data signal Data. One terminal of the light-emitting device 60 is connected to the pixel circuit, and the other terminal of the light-emitting device 60 is connected to the second power signal Pvee.

The pixel circuit provided by the embodiment of FIG. 15 is an optional implementation of the present disclosure, and the structure of the pixel circuit is not limited by the embodiment of the present disclosure. The pixel circuit may be an aTbC structure, that is, including a transistors and b capacitors, where a and b are positive integers.

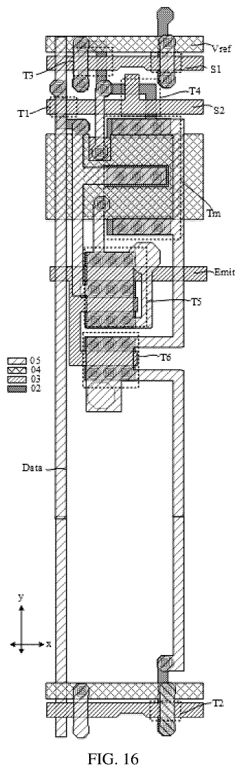

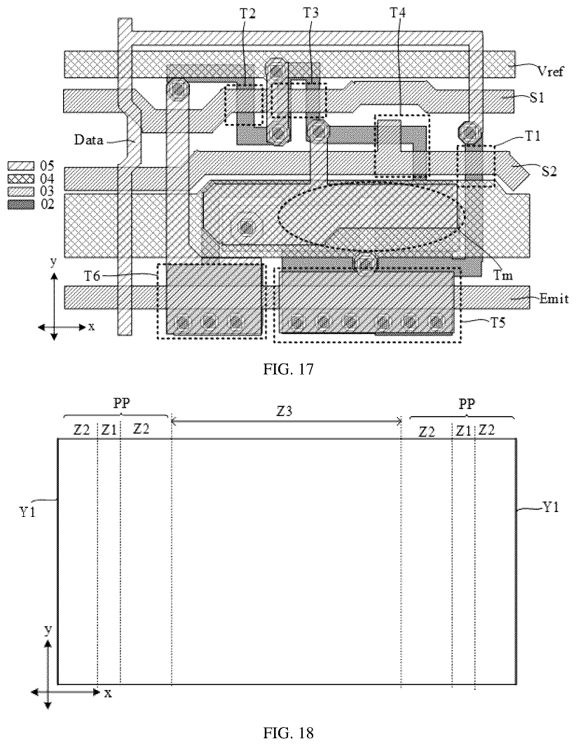

FIG. 16 is a schematic diagram of a pixel circuit in a second region according to an embodiment of the present disclosure. FIG. 17 is a schematic diagram of a pixel circuit in a third region according to an embodiment of the present disclosure. FIG. 16 and FIG. 17 may be understood in combination with FIG. 15. As can be seen from FIG. 16 and FIG. 17, a scanning signal line S1, a scanning signal line S2, a light-emitting control signal line Emit, a reset signal line Vref, and a data signal line Data are further provided in the display panel, and each signal line and the signal thereof are labeled the same.

As can be seen from FIG. 16 and FIG. 17, a length of the driving transistor Tm of the pixel circuit 30 in the second region Z2 in the first direction x is less than a length of the driving transistor Tm of the pixel circuit 30 in the third region Z3 in the first direction x, and a length of the driving transistor Tm of the pixel circuit 30 in the second region Z2 in the second direction y is greater than a length of the driving transistor Tm of the pixel circuit 30 in the third region Z3 in the second direction y, where the second direction y intersects with the first direction x. Such arrangement facilitates manufacturing and realizing that a length of the pixel circuit 30 in the second region Z2 in the first direction x is less than a length of the pixel circuit 30 in the third region Z3 in the first direction x, so that a sufficient number of pixel circuits 30 can be densely arranged in the second region Z2 to meet the driving of the light-emitting devices in the first region Z1. In an example, a width-to-length ratio of the driving transistor Tm in the second region Z2 can be set to be the same as a width-to-length ratio of the driving transistor Tm in the third region Z3, to ensure consistent driving performance of the pixel circuits 30 in different regions. A width-to-length ratio of a transistor refers to a ratio of a channel width to a channel length of the transistor.

In an example, width-to-length ratios of transistors having the same function in the pixel circuits 30 in the second region Z2 and the third region Z3 are the same, so that the driving performance of the pixel circuits 30 in the two regions is the same, thereby improving the display uniformity within the display panel.

In some implementations, FIG. 18 is another schematic diagram of a display panel according to an embodiment of the present disclosure, and FIG. 18 shows a distribution of regions in the display region. As shown in FIG. 18, the display panel includes a first edge Y1 extending along a second direction y, and the second direction y intersects with the first direction x. The first region Z1 and the second regions Z2 located on both sides of the first region Z1 together form a first arrangement region PP, and the first arrangement region PP is located on a side of the third region Z3 close to the first edge Y1. That is, the first arrangement region PP is arranged at a position close to an edge of the display panel. As shown in FIG. 18, first arrangement region PP is arranged on the left and right sides of the display panel. On the one hand, when the shift register unit 10 drives pixel rows in the display panel, a driving signal is transmitted from the left and right sides to the middle, which can improve the transmission uniformity of the driving signal. On the other hand, arranging the second region Z2 in which the pixel circuits 30 are densely arranged close to the edge can ensure high and uniform transmittance in the central region when the display panel is applied to the transparent display, thereby ensuring the transparent display effect.

In an embodiment of the present disclosure, the shift register units 10 include light-emitting shift register units and scanning shift register units, the light-emitting shift register units are cascaded, and the scanning shift register units are cascaded. The light-emitting shift register unit is configured to provide the light-emitting control signal Emit in the embodiment of FIG. 15, and the scanning shift register unit is configured to provide the scanning signal S1 and/or the scanning signal S2 in the embodiment of FIG. 15. The light-emitting shift register units and the scanning shift register units may be arranged in one first region Z1, or may be respectively arranged in different first regions Z1.

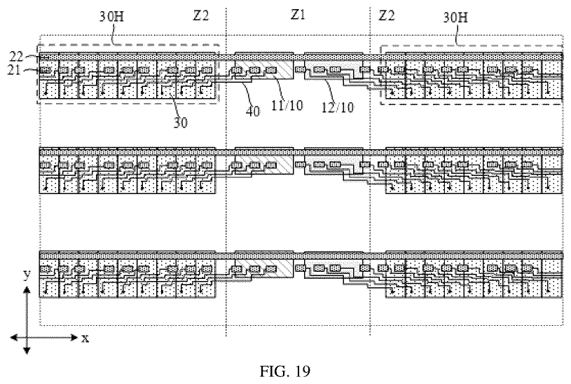

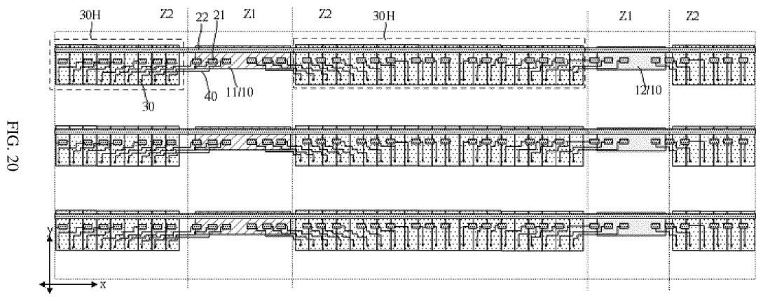

In some implementations, FIG. 19 is another partial schematic diagram of a display panel according to an embodiment of the present disclosure. As shown in FIG. 19, the shift register units 10 include light-emitting shift register units 11 and scanning shift register units 12, the light-emitting shift register units 11 are cascaded, and the scanning shift register units 12 are cascaded. The light-emitting shift register unit 11 and the scanning shift register unit 12 in the first region Z1 are adjacent in the first direction x. The light-emitting shift register units 11 and the scanning shift register units 12 overlap with the circuit rows 30H in the second region Z2 in the first direction x. An output terminal of the light-emitting shift register unit 11 is connected to a control terminal of the first light-emitting control transistor T5 and a control terminal of the second light-emitting control transistor T6 in the circuit row 30H through a signal line. An output terminal of the scanning shift register unit 12 is connected to a control terminal of the data writing transistor T1 and a control terminal of the threshold compensation transistor T4 in one circuit row 30H through a signal line, and is connected to a control terminal of the gate reset transistor T3 in another circuit row 30H through another signal line.

In the embodiment of FIG. 19, the light-emitting shift register units 11 and the scanning shift register units 12 are arranged in the same first region Z1, and the first electrodes 21 in the first region Z1 are connected to the pixel circuits 30 on both sides by arranging the connection lines 40 extending leftwards and rightwards, thereby reducing the number of the connection lines 40 arranged on one side, and reducing the area occupied by the connection lines 40 on one side. The application in transparent display can improve the display effect of transparent display.

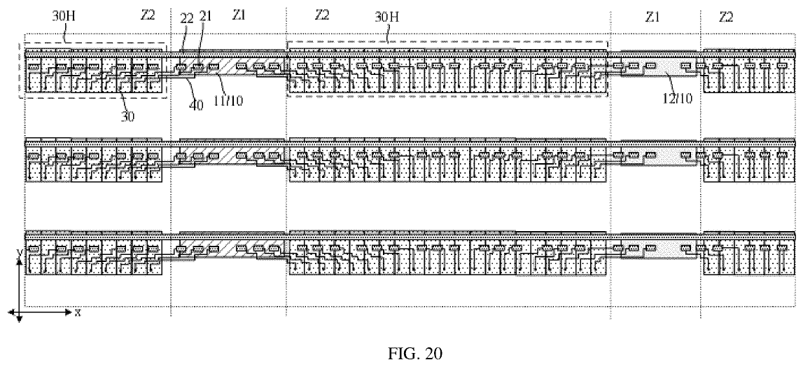

In some other implementations, the light-emitting shift register units 11 and the scanning shift register units 12 are located in different first regions Z1. FIG. 20 is another partial schematic diagram of a display panel according to an embodiment of the present disclosure. As shown in FIG. 20, the shift register units 10 include light-emitting shift register units 11 and scanning shift register units 12, the light-emitting shift register units 11 are cascaded, and the scanning shift register units 12 are cascaded. The light-emitting shift register units 11 and the scanning shift register units 12 are located in different first regions Z1. The plurality of first electrodes 21 in the first region Z1 where the light-emitting shift register units 11 are located are respectively connected to the corresponding pixel circuits 30 in the two second regions Z2 on both sides through the connection lines 40 extending leftwards and rightwards. The plurality of first electrodes 21 in the first region Z1 where the scanning shift register units 12 are located are respectively connected to the corresponding pixel circuits 30 in the two second regions Z2 on both sides through the connection lines 40 extending leftwards and rightwards. When the PPI of the display panel is determined, the light-emitting shift register units 11 and the scanning shift register units 12 are arranged in different first regions Z1, which can reduce the number of the first electrodes 21 arranged in each first region Z1, and correspondingly reduce the number of the connection lines 40 extending leftwards and rightwards in the first region Z1, thereby further reducing the space occupied by the connection lines 40 arranged in the second region Z2.

As shown in FIG. 20, the number of the first electrodes 21 in the first region Z1 where the light-emitting shift register units 11 are located is different from the number of the first electrodes 21 in the first region Z1 where the scanning shift register units 12 are located. A circuit structure of the light-emitting shift register unit 11 and a circuit structure of the scanning shift register unit 12 may be different, the shift register unit 10 shown in FIG. 3 may be the light-emitting shift register unit 11, and the shift register unit 10 shown in FIG. 5 may be the scanning shift register unit 12, so that a length of the light-emitting shift register unit 11 and a length of the scanning shift register unit 12 in the first direction x are different. When the light-emitting shift register units 11 and the scanning shift register units 12 are respectively arranged in two first regions Z1, and the first electrodes 21 in the display region are arranged regularly at the same time, the number of the first electrodes 21 in the two first regions Z1 may be different.

It can be understood in combination with the embodiment of FIG. 18 that two first regions Z1 can be respectively arranged on left and right sides of the display panel in the first direction x, that is, there are a total of four first regions Z1. Light-emitting shift register units 11 and scanning shift register units 12 are respectively arranged in two first regions Z1 on one side of the display panel, and the first region Z1 of the light-emitting shift register units 11 is located on a side of the first region Z1 of the scanning shift register units 12 close to an edge of the display panel. That is, the scanning shift register units 12 are arranged closer to the interior of display panel than the light-emitting shift register units 11. Such arrangement facilitates the transmission of the scanning signal output by the scanning shift register unit 12, and facilitates the uniformity of the scanning signal in a row of pixels connected to the scanning shift register unit 12, thereby improving the display uniformity.

In some implementations, as shown in FIG. 20, a second region Z2 is provided between the first region Z1 where the light-emitting shift register units 11 are located and the first region Z1 where the scanning shift register units 12 are located. That is, when the light-emitting shift register units 11 and the scanning shift register units 12 are arranged in different first regions Z1, two second regions Z2 corresponding to the light-emitting shift register units 11 and the scanning shift register units 12 are continuously arranged, that is, regions in which the pixel circuits 30 are densely arranged are continuously arranged. It can be understood in combination with the embodiment of FIG. 7 that the display panel is further provided with a third region Z3 in which the pixel circuits 30 are conventionally arranged, and the arrangement of the pixel circuits 30 in the second region Z2 is different from the arrangement of the pixel circuits 30 in the third region Z3. The better the regularity of a metal pattern in a metal patterning process for manufacturing the display panel, the better the uniformity of the overall pattern, and the better the consistency of the characteristics of the manufactured transistor. The design of the embodiment of FIG. 20 can avoid multiple mutations of the metal pattern in the metal patterning process, and improve the performance consistency of the pixel circuit transistors in the second region Z2 and the third region Z3, thereby improving the display uniformity.

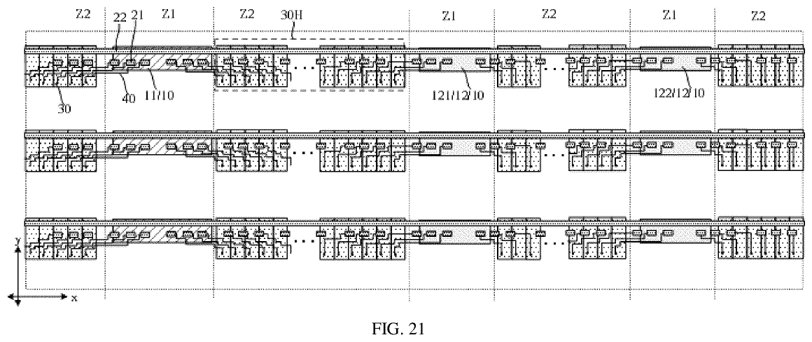

In some implementations, FIG. 21 is another partial schematic diagram of a display panel according to an embodiment of the present disclosure. As shown in FIG. 21, the scanning shift register units 12 further includes first scanning shift register units 121 and second scanning shift register units 122, the first scanning shift register units 121 are cascaded, and the second scanning shift register units 122 are cascaded. The first scanning shift register units 121 and the second scanning shift register units 122 are located in different first regions Z1. For example, an output terminal of the first scanning shift register unit 121 is connected to a control terminal of the gate reset transistor T3 in the circuit row 30H through a signal line, and an output terminal of the second scanning shift register unit 122 is connected to control terminals of the data writing transistor T1 and the threshold compensation transistor T4 in the circuit row 30H through a signal line. When the size of the display panel in the first direction x is relatively large, two groups of scanning shift register units are provided to respectively drive the gate reset transistor T3 and the data writing transistor T1 (i.e., the threshold compensation transistor T4), which can improve the driving capability of the scanning signal and meet the driving requirements of large size. In addition, when two groups of scanning shift register units are provided in the display region, the shift register units occupy more positions in the display region, and the number of misalignments between the first electrodes 21 and the pixel circuits 30 increases. The first scanning shift register units 121 and the second scanning shift register units 122 are arranged in different first regions Z1, which can also reduce the number of the first electrodes 21 arranged in each first region Z1, and correspondingly reduce the number of the connection lines 40 extending leftwards and rightwards in the first region Z1, thereby further reducing the space occupied by the connection lines 40 arranged in the second region Z2.

It can be understood in combination with the embodiment of FIG. 18 that three first regions Z1 can be respectively arranged on left and right sides of the display panel in the first direction x, that is, there are a total of six first regions Z1. Light-emitting shift register units 11, first scanning shift register units 121 and second scanning shift register units 122 are respectively provided in the three first regions Z1 on one side of the display panel. The first region Z1 of the light-emitting shift register units 11 is located on a side of the first regions Z1 of the two groups of scanning shift register units close to an edge of the display panel. That is, the first scanning shift register units 121 and the second scanning shift register units 122 are arranged closer to the interior of the display panel than the light-emitting shift register units 11. Such arrangement facilitates the transmission of the scanning signal output by the scanning shift register unit 12, and facilitates the uniformity of the scanning signal in a row of pixels connected to the scanning shift register unit 12, thereby improving the display uniformity.

As shown in FIG. 21, a second region Z2 is provided between the first region Z1 where the first scanning shift register units 121 are located and the first region Z1 where the second scanning shift register units 122 are located. That is, the two second regions Z2 corresponding to the first scanning shift register units 121 and the second scanning shift register units 122 are continuously arranged, that is, regions in which the pixel circuits 30 are densely arranged are continuously arranged. In this way, multiple mutations of the metal pattern can be avoided in the metal patterning process, the performance consistency of the pixel circuit transistors in the second region Z2 and the third region Z3 is improved, thereby improving the display uniformity.

As shown in FIG. 16 and FIG. 17, to drive the pixel circuits 30, a reset signal line Vref, a scanning signal line S1, a scanning signal line S2, and a light-emitting control signal line Emit extending in the first direction x need to be provided in the display panel. In a region where the pixel circuits 30 are located, the reset signal line Vref is located in the second metal layer 04, and the scanning signal line S1, the scanning signal line S2, and the light-emitting control signal line Emit are located in the first metal layer 03.

In an embodiment of the present disclosure, the shift register units 10 are arranged in the first region Z1 in the display region, and the shift register units 10 overlap with the pixel circuits 30 in the first direction x, which is equivalent to arranging the shift register units 10 between the pixel circuits 30 arranged along the first direction x. It can be understood in combination with the film layer structure of FIG. 8 that at least a semiconductor layer 02, a first metal layer 03, a second metal layer 04 and a third metal layer 05 in the display panel need to be used in manufacturing the pixel circuit 30. As shown in FIG. 3 or FIG. 5, the shift register unit 10 includes a plurality of transistors, and at least a semiconductor layer 02, a first metal layer 03, a second metal layer 04, and a third metal layer 05 in the display panel need to be used in manufacturing the shift register unit 10. In order to satisfy the wiring requirement of the signal lines for driving the pixel circuits 30 while arranging the shift register unit 10 in the Display region, in an embodiment of the present disclosure, the signal lines extending along the first direction x are further designed.

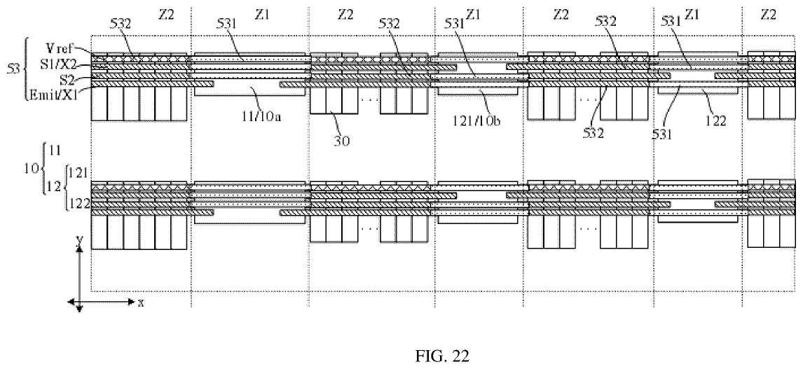

In some implementations, FIG. 22 is another partial schematic diagram of a display panel according to an embodiment of the present disclosure. FIG. 22 shows a simplified schematic diagram of the pixel circuits 30 and the shift register units, and FIG. 22 does not show connection lines extending leftwards and rightwards from the first region Z1 to two sides of the second regions Z2. As shown in FIG. 22, the display region includes a first region Z1 and a second region Z2, the display region includes first signal lines 53 extending along a first direction x, and the first signal lines 53 pass through the first region Z1 and the second region Z2 in the first direction x. The pixel circuits 30 are electrically connected to the first signal lines 53. Each of the first signal lines 53 includes a first line segment 531 and a second line segment 532 arranged in different layers. The first line segment 531 and the second line segment 532 are connected to each other. The first line segment 531 is located in the first region Z1, and the second line segment 532 is at least partially located in the second region Z2. The first signal lines 53 include at least one of a reset signal line Vref, a scanning signal line S1, a scanning signal line S2, and a light-emitting control signal line Emit.

In the embodiment of the present disclosure, the first signal line 53 extending along the first direction x is designed, and line segments of the first signal line 53 in a region of the pixel circuits 30 and a region of the shift register units 10 are located in different film layers. The first signal line 53 adopts a line-switching design when extending to the first region Z1 where the shift register units 10 are located. As a result, this can prevent the first signal line 53 from being short-circuited with the structure of the shift register units 10 when the first signal line 53 extends to the first region Z1 using a single-layer routing design. A wiring requirement of the first signal line 53 and a wiring requirement of the shift register unit 10 are met by reasonable wiring.

As shown in FIG. 22, the shift register units 10 includes light-emitting shift register units 11, first scanning shift register units 121 and second scanning shift register units 122. The light-emitting control signal line Emit is connected to an output terminal of the light-emitting shift register unit 11, the scanning signal line S1 is connected to an output terminal of the first scanning shift register unit 121, and the scanning signal line S2 is connected to an output terminal of the second scanning shift register unit 122.

In an embodiment of the present disclosure, the shift register units 10 includes first shift register units 10a and second shift register units 10b, the first shift register units 10a are cascaded, and the second shift register units 10b are cascaded. The first signal lines 53 includes a first gating line X1 and a second gating line X2. The first gating line X1 is connected to an output terminal of the first shift register unit 10a, and the second gating line X2 is connected to an output terminal of the second shift register unit 10b. Taking the light-emitting shift register unit 11 as the first shift register unit 10a and the first scanning shift register unit 121 as the second shift register unit 10b in FIG. 22 as an example, the light-emitting control signal line Emit is the first gating line X1, and the scanning signal line S1 is the second gating line X2. It can be seen from the top view of FIG. 22 that, along a direction perpendicular to the plane of the display panel, a first line segment 531 of the first gating line X1 is insulated from and overlaps with the second shift register unit 10b, and a first line segment 531 of the second gating line X2 is insulated from and overlaps with the first shift register unit 10a. The first shift register unit 10a and the second shift register unit 10b are two shift register units providing different signals. A gating line connected to an output terminal of the first shift register unit 10a overlaps with the second shift register unit 10b when extending to a position of the second shift register unit 10b, and a gating line connected to an output terminal of the second shift register unit 10b overlaps with the first shift register unit 10a when extending to a position of the first shift register unit 10a. In the embodiment of the present disclosure, the first line segment 531 located in the first region Z1 and the second line segment 532 at least partially located in the second region Z2 are designed to be located in different film layers, which can ensure that the gating line and the shift register unit 10 not connected thereto can be insulated and overlapped to avoid short circuit.

In the embodiment of the present disclosure, a line-switching design is used for the first signal line 53. A portion of the first signal line 53 located in the first region Z1 is arranged to be insulated from and overlap with the shift register unit 10 not connected thereto, rather than the first signal line 53 being wound at the position of the shift register unit 10 not connected thereto, so that the first signal line 53 and the shift register unit 10 are not connected to each other. In this way, the space occupied by the wiring in the first region Z1 can be reduced, and the transmittance of the first region Z1 can be improved when the display panel is applied to transparent display.

Taking the light-emitting shift register unit 11 as the first shift register unit 10a and the first scanning shift register unit 121 as the second shift register unit 10b as an example, the overlapping situation of the line segment of the first signal line 53 located in the first region Z1 and the shift register unit 10 is described above. It can be understood in combination with FIG. 22 that the first signal lines 53 includes a scanning signal line S1, which includes a first line segment 531 and a second line segment 532. One first line segment 531 of the scanning signal line S1 overlaps with the light-emitting shift register unit 11, and one first line segment 531 of the scanning signal line S1 overlaps with the second scanning shift register unit 122.

The first signal lines 53 includes a scanning signal line S2, which includes a first line segment 531 and a second line segment 532. One first line segment 531 of the scanning signal line S2 overlaps with the light-emitting shift register unit 11, and one first line segment 531 of the scanning signal line S2 overlaps with the first scanning shift register unit 121.

The first signal lines 53 includes a light-emitting control signal line Emit, which includes a first line segment 531 and a second line segment 532. One first line segment 531 of the light-emitting control signal line Emit overlaps with the first scanning shift register unit 121, and one first line segment 531 of the light-emitting control signal line Emit overlaps with the second scanning shift register unit 122.

FIG. 22 shows shift register units 10 arranged in one first region Z1. As shown in the embodiment of FIG. 19, the light-emitting shift register units 11 and the scanning shift register units 12 are located in the same first region Z1. In this embodiment, the light-emitting control signal line Emit and the scanning signal line S1/S2 also need to adopt the line-switching design shown in the embodiment of FIG. 22. When the light-emitting control signal line Emit extends to the position of the scanning shift register unit 12, the light-emitting control signal line Emit is switched to the first line segment 531 for routing, to avoid the short circuit between the light-emitting control signal line Emit and the scanning shift register unit 12. When the scanning signal line S1 or the scanning signal line S2 extends to the position of the light-emitting shift register unit 11, the scanning signal line S1 or the scanning signal line S2 is switched to the first line segment 531 for routing, to avoid the short circuit between the scanning signal line and the light-emitting shift register unit 11.

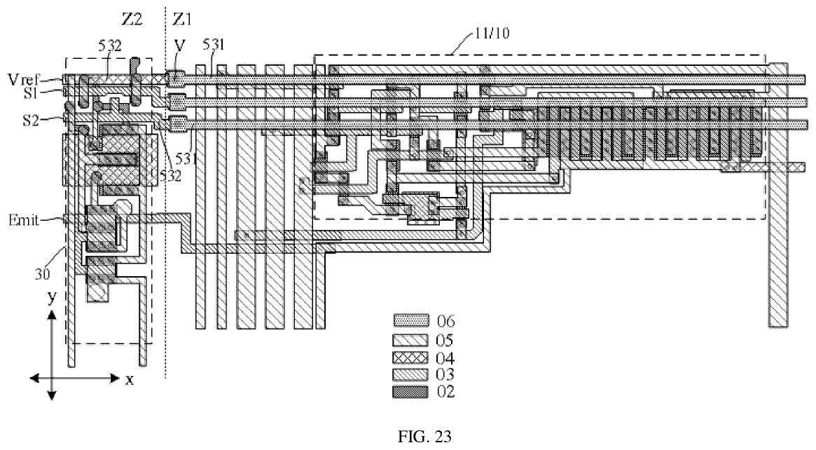

FIG. 23 is another partial schematic diagram of a display panel according to an embodiment of the present disclosure, and FIG. 23 shows a wiring situation at a position of a light-emitting shift register unit 11. The transistor structure of the shift register unit in FIG. 23 can be understood with reference to FIG. 3, and is not labeled in FIG. 23. It can be seen from FIG. 23 that an output terminal of the light-emitting shift register unit 11 is electrically connected to the light-emitting control signal line Emit. The scanning signal line S1 includes a first line segment 531 and a second line segment 532, and the scanning signal line S2 includes the first line segment 531 and the second line segment 532. The first line segment 531 of the scanning signal line S1 located in the first region Z1 overlaps with the light-emitting shift register unit 11, and the first line segment 531 of the scanning signal line S2 located in the first region Z1 overlaps with the light-emitting shift register unit 11. FIG. 23 shows that for a first line segment 531 and a second line segment 532 on one signal line, the first line segment 531 and the second line segment 532 are electrically connected through a via hole V.

In some implementations, as shown in FIG. 22 and FIG. 23, the first signal lines 53 includes a reset signal line Vref, which includes a first line segment 531 and a second line segment 532. In a direction perpendicular to the plane of the display panel, the first line segment 531 of the reset signal line Vref is insulated from and overlaps with the shift register unit 10. It can be seen from FIG. 23 that, when the reset signal line Vref extends to the first region Z1 where the shift register unit 10 is located along the first direction x, the reset signal line Vref may be short-circuited with the via hole in the shift register unit 10 if the line-switching design is not adopted, and the space occupied by wiring is increased if the reset signal line Vref adopts a winding design. Therefore, in the embodiment of the present disclosure, the reset signal line Vref also adopts the line-switching design when extending to the first region Z1, which not only can prevent the reset signal line Vref from being short-circuited with the shift register unit 10, but also can save the wiring space of the first region Z1, thereby facilitating the application of transparent display.

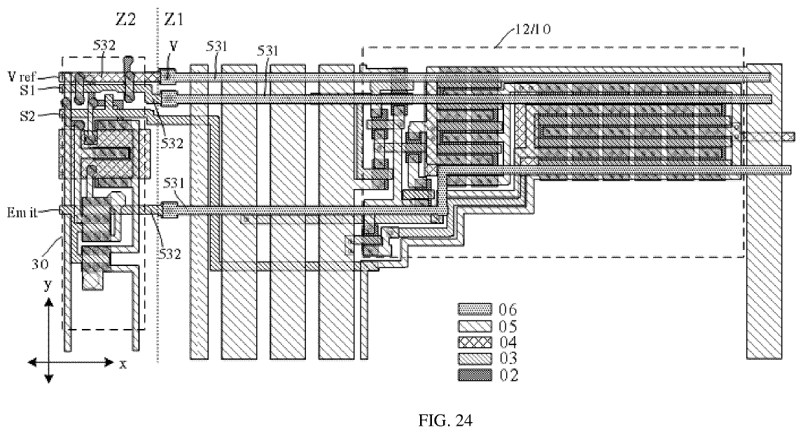

FIG. 24 is another partial schematic diagram of a display panel according to an embodiment of the present disclosure, and FIG. 24 shows a wiring situation at a position of a shift register unit 12. The transistor structure of the shift register unit in FIG. 24 can be understood with reference to FIG. 5, and is not labeled in FIG. 24. It can be seen from FIG. 24 that an output terminal of the scanning shift register unit 12 is electrically connected to the scanning signal line S2. The scanning signal line S1 includes a first line segment 531 and a second line segment 532, and the first line segment 531 of the scanning signal line S1 located in the first region Z1 overlaps with the scanning shift register unit 12. The light-emitting control signal line Emit includes a first line segment 531 and a second line segment 532, and the first line segment 531 of the light-emitting control signal line Emit located in the first region Z1 overlaps with the scanning shift register unit 12. The reset signal line Vref includes a first line segment 531 and a second line segment 532, and the first line segment 531 of the reset signal line Vref located in the first region Z1 is insulated from and overlaps with the scanning shift register unit 12. FIG. 24 shows that for a first line segment 531 and a second line segment 532 on one signal line, the first line segment 531 and the second line segment 532 are electrically connected through a via hole V.

In combination with the embodiment of FIG. 22, FIG. 24 shows the wiring situation at the position of the second scanning shift register unit 122 in the embodiment of FIG. 22. In the embodiment of FIG. 22, the first scanning shift register unit 121 can adopt a structural design similar to the second scanning shift register unit 122. At the position of the first scanning shift register unit 121, an output terminal of the first scanning shift register unit 121 is electrically connected to the scanning signal line S1. The scanning signal line S1, the light-emitting control signal line Emit and the reset signal line Vref respectively include a first line segment 531 and a second line segment 532, and the first line segment 531 of each signal line overlaps with the first scanning shift register unit 121.

In combination with the film layer structure shown in FIG. 8, the display panel includes a circuit layer 001 including at least a semiconductor layer 02, a first metal layer 03, a second metal layer 04, and a third metal layer 05 that are located above the substrate 00. The pixel circuits 30 and the shift register units 10 are made in the circuit layer 001. The film layer of the first line segment 531 is located between the circuit layer 001 and the film layer of the first electrodes 21. Alternatively, the first line segment 531 is located in the fourth metal layer 06. Such arrangement can ensure that the arrangement of the first line segment 531 does not affect the original layout of the pixel circuits 30 and the shift register units 10, and a power supply structure is provided in the fourth metal layer 06. The first line segment 531 and the power supply structure are manufactured in the same process without adding a new process. In addition, the film layer where the first line segment 531 is located may be made of a material with a lower resistivity, so that the resistance of the first line segment 531 is lower, thereby reducing the overall resistance of the first signal line 53 and reducing the voltage drop of signal transmission.

In some implementations, materials used to make the first metal layer 03 and the second metal layer 04 include molybdenum, and materials used to make the third metal layer 05 and the fourth metal layer 06 include aluminum and titanium. Alternatively, the third metal layer 05 and the fourth metal layer 06 are a three-layer structure of titanium-aluminum-titanium.

In some implementations, the scanning signal line S1 includes a first line segment 531 and a second line segment 532. A film layer of the first line segment 531 is located between the circuit layer 001 and a film layer of the first electrodes 21. The first line segment 531 is located in the fourth metal layer 06, and the second line segment 532 is located in the first metal layer 03.

In some implementations, the scanning signal line S2 includes a first line segment 531 and a second line segment 532. The first line segment 531 is located in the fourth metal layer 06, and the second line segment 532 is located in the first metal layer 03.

In some implementations, the light-emitting control signal line Emit includes a first line segment 531 and a second line segment 532. The first line segment 531 is located in the fourth metal layer 06, and the second line segment 532 is located in the first metal layer 03.

In some implementations, the reset signal line Vref includes a first line segment 531 and a second line segment 532. The first line segment 531 is located in the fourth metal layer 06, and the second line segment 532 is located in the second metal layer 04.

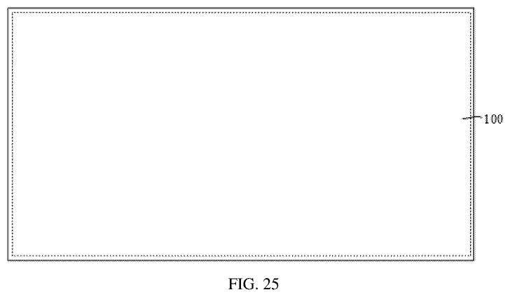

Based on the same inventive concept, an embodiment of the present disclosure further provides a display device. FIG. 25 is a schematic diagram of a display device according to an embodiment of the present disclosure. As shown in FIG. 25, the display device includes the display panel 100 provided by any embodiment of the present disclosure. The structure of the display panel has been described in the above-mentioned embodiments, and will not be repeated herein. The display device provided by the embodiments of the present disclosure may be, for example, an electronic device having a display function, such as a mobile phone, a tablet, a computer, a television, and a smart wearable product. The display device provided by the embodiments of the present disclosure may also be a transparent display device, such as a transparent display window; or may also be a spliced display device, such as a large conference room screen, and a large exhibition hall screen.

The above description merely illustrates some preferred embodiments of the present disclosure and is not intended to limit the present disclosure, and any modification, equivalent substitution, improvement and the like made within a spirit and a principle of the present disclosure shall fall with a scope of the present disclosure.

Finally, it should be noted that, the above-described embodiments are merely for illustrating the present disclosure but not intended to provide any limitation. Although the present disclosure has been described in detail with reference to the above-described embodiments, it should be understood by those skilled in the art that, it is still possible to modify the technical solutions described in the above embodiments or to equivalently replace some or all of the technical features therein, but these modifications or replacements do not cause the essence of corresponding technical solutions to depart from the scope of the present disclosure.

What is claimed is:

1. A display panel, wherein a display region of the display panel comprises shift register units, first electrodes and pixel circuits, and one of the first electrodes is electrically connected to a respective one of the pixel circuits;
the display region comprises at least one first region and at least two second regions, two second regions are located on two sides of a respective first region along a first direction, the at least one first region comprises the shift register units and the first electrodes, and the at least two second regions comprise the pixel circuits and the first electrodes; and
the pixel circuits connected to n first electrodes of the first electrodes in the respective first region are located in one of the two second regions, and the pixel circuits connected to m first electrodes of the first electrodes in the respective first region are located in the other one of the two second regions, wherein n and m are both positive integers.

2. The display panel according to claim 1, wherein the pixel circuits in the second region are arranged in circuit rows in the first direction; and
in the first direction, the shift register units respectively overlap with the circuit rows.

3. The display panel according to claim 2, wherein one of the shift register units comprises an output module and a driving module, and the output module and the driving module are arranged in the first direction.

4. The display panel according to claim 1, further comprising:
a plurality of connection lines, wherein the plurality of connection lines comprise first connection lines and second connection lines, the first connection lines extend from the first region to the second region, and the second connection lines are located in the second region; and
the first connection lines are connected between the first electrodes in the first region and the pixel circuits electrically connected thereto, and the second connection lines are connected between at least some of the first electrodes in the second region and the pixel circuits electrically connected thereto.

5. The display panel according to claim 4, wherein at least some of the connection lines respectively comprise at least one first line sub-segment and at least one second line sub-segment, the at least one first line sub-segment and the at least one second line sub-segment are connected to each other, the at least one first line sub-segment extends along the first direction, the at least one second line sub-segment extends along a second direction, and the second direction intersects with the first direction; or
wherein the pixel circuits in the second region are arranged in circuit rows in the first direction, and the connection lines located in the second region at least partially overlap with the circuit rows in a direction perpendicular to a plane of the display panel; or
wherein the connection lines and the first electrodes are located in a same layer; or
wherein the pixel circuits in the second region comprise first pixel circuits and second pixel circuits, the connection lines are connected between the first pixel circuits and the first electrodes connected thereto, the second pixel circuits overlap with the first electrodes connected thereto along a direction perpendicular to a plane of the display panel, and a plurality of first pixel circuits arranged in the first direction form a pixel circuit group, and at least one second pixel circuit is located between two adjacent pixel circuit groups.

6. The display panel according to claim 1, wherein the display region further comprises second electrodes and light-emitting devices, and one of the first electrodes and a respective one of the second electrodes form an electrode pair;
two terminals of one of the light-emitting devices are respectively electrically connected to a first electrode and a second electrode in one electrode pair; and
the display region is divided into a plurality of electrode groups, and one of the electrode groups comprises N electrode pairs, wherein N is a positive integer, and N≥2.

7. The display panel according to claim 6, wherein in at least one of the electrode groups in the respective first region, the pixel circuits connected to n1 first electrodes of the first electrodes are located in one of the two second regions, and the pixel circuits connected to n2 first electrodes of the first electrodes are located in the other one of the two second regions, wherein n1 and n2 are both positive integers, and n1+n2=N; or
wherein for at least one of the electrode groups, n3 first electrodes of the first electrodes are located in the first region, and n4 first electrodes of the first electrodes are located in the second region, wherein n3 and n4 are both positive integers, and n3+n4=N; or
wherein colors of N light-emitting devices of the light-emitting devices connected to one of the electrode groups are different from one another.

8. The display panel according to claim 1, wherein the display region comprises a driving signal line and a second signal line extending along a second direction, the second direction intersects with the first direction, the shift register units are electrically connected to the driving signal line, and the pixel circuits are electrically connected to the second signal line; and wherein along a direction perpendicular to a plane of the display panel, at least one of the first electrodes overlaps with the driving signal line and the shift register units, and/or at least one of the first electrodes overlaps with the driving signal line and the second signal line, and/or at least one of the first electrodes overlaps with the second signal line and the pixel circuits, and/or at least one of the first electrodes overlaps with the driving signal line and the pixel circuits; or
wherein the display region comprises a driving signal line and a second signal line extending along a second direction, the second direction intersects with the first direction, the shift register units are electrically connected to the driving signal line, and the pixel circuits are electrically connected to the second signal line; wherein the display region further comprises a redundant electrode, the redundant electrode and one of the first electrodes are connected to a same one of the pixel circuits, and one of the first electrodes is provided with at least one redundant electrode; and wherein in a direction perpendicular to a plane of the display panel, the at least one redundant electrode overlaps with the driving signal line, and/or the at least one redundant electrode overlaps with the second signal line.

9. The display panel according to claim 1, wherein the display region further comprises a third region comprising the pixel circuits and the first electrodes; and
an arrangement density of the pixel circuits in the third region is less than an arrangement density of the pixel circuits in the second region.

10. The display panel according to claim 9, wherein a length of one of the pixel circuits in the second region along the first direction is less than a length of one of the pixel circuits in the third region along the first direction, and/or a length of one of the pixel circuits in the second region along a second direction is greater than a length of one of the pixel circuits in the third region along the second direction, wherein the second direction intersects with the first direction; or
wherein the pixel circuits respectively comprise a driving transistor, a length of the driving transistor in the second region along the first direction is less than a length of the driving transistor in the third region along the first direction, a length of the driving transistor in the second region along a second direction is greater than a length of the driving transistor in the third region along the second direction, and the second direction intersects with the first direction; or
wherein the display panel further comprises a first edge extending in a second direction, the second direction intersects with the first direction, and the respective first region and the two second regions located on both sides thereof together form a first arrangement region that is located on a side of the third region close to the first edge.

11. The display panel according to claim 1, wherein the shift register units comprise light-emitting shift register units and scanning shift register units, the light-emitting shift register units are cascaded, and the scanning shift register units are cascaded; and
the light-emitting shift register units and the scanning shift register units in the first region are adjacent in the first direction.

12. The display panel according to claim 1, wherein the shift register units comprise light-emitting shift register units and scanning shift register units, the light-emitting shift register units are cascaded, and the scanning shift register units are cascaded; and
the light-emitting shift register units and the scanning shift register units are located in different first regions.

13. The display panel according to claim 12, wherein a number of the first electrodes in a first region of the light-emitting shift register units is different from a number of the first electrodes in a first region of the scanning shift register units.

14. The display panel according to claim 13, wherein a second region is provided between the first region of the light-emitting shift register units and the first region of the scanning shift register units.

15. The display panel according to claim 14, wherein the scanning shift register units further comprise first scanning shift register units and second scanning shift register units, the first scanning shift register units are cascaded, the scanning shift register units are cascaded, and the first scanning shift register units and the second scanning shift register units are located in different first regions.

16. The display panel according to claim 15, wherein a second region is provided between a first region of the first scanning shift register units and a first region of the second scanning shift register units.

17. The display panel according to claim 1, wherein the display region comprises a first signal line extending along the first direction, the pixel circuits are electrically connected to the first signal line, and the first signal line comprises a first line segment and a second line segment arranged in different layers; and
the first line segment and the second line segment are connected to each other, the first line segment is located in the first region, and the second line segment is at least partially located in the second region.

18. The display panel according to claim 17, wherein the shift register units comprise first shift register units and second shift register units, the first shift register units are cascaded, and the second shift register units are cascaded; wherein the first signal line comprises a first gating line and a second gating line, the first gating line is connected to output terminals of the first shift register units, and the second gating line is connected to output terminals of the second shift register units; and wherein along a direction perpendicular to a plane of the display panel, the first line segment of the first gating line is insulated from and overlaps with the second shift register units, and the first line segment of the second gating line is insulated from and overlaps with the first shift register units; or
wherein the first signal line comprises a reset signal line; and along a direction perpendicular to a plane of the display panel, the first line segment of the reset signal line is insulated from and overlaps with the shift register units.

19. The display panel according to claim 17, further comprising:
a circuit layer, wherein the pixel circuits and the shift register units are located in the circuit layer, and a film layer of the first line segment is located between the circuit layer and a film layer of the first electrodes.

20. A display device, comprising a display panel, wherein a display region of the display panel comprises shift register units, first electrodes and pixel circuits, and one of the first electrodes is electrically connected to a respective one of the pixel circuits;
the display region comprises at least one first region and at least two second regions, two second regions are located on two sides of a respective first region along a first direction, the at least one first region comprises the shift register units and the first electrodes, and the at least two second regions comprise the pixel circuits and the first electrodes; and
the pixel circuits connected to n first electrodes of the first electrodes in the respective first region are located in one of the two second regions, and the pixel circuits connected to m first electrodes of the first electrodes in the respective first region are located in the other one of the two second regions, wherein n and m are both positive integers.
